(19) United States
(12) Patent Application Publication
(10) Pub. No.: US 2025/0202451 A1
(43) Pub. Date: Jun. 19, 2025

(54) SUPPORT LAYER SUBSTRATE, COMPOSITE SUBSTRATE, AND ELECTRONIC DEVICE

(71) Applicant: QUANZHOU SANAN INTEGRATED CIRCUIT CO.,LTD., Quanzhou (CN)

(72) Inventors: Minghui FANG, Quanzhou (CN); Zhonghe LIN, Quanzhou (CN); Shihwei HUANG, Quanzhou (CN); Shaoping LIN, Quanzhou (CN); Shengyu YANG, Quanzhou (CN)

(21) Appl. No.: 18/900,916

(22) Filed: Sep. 30, 2024

(30) Foreign Application Priority Data
Dec. 19, 2023 (CN) 202311754631.8

(51) Int. Cl. H03H 9/02; H01L 29/34

(52) U.S. Cl. CPC H03H 9/02559; H10D 62/57

(57) ABSTRACT

A support layer substrate, a composite substrate and an electronic device are provided. The support layer substrate has a main support surface, each sampling area on the main support surface achieves a target roughness, and each sampling area is defined as an area with a length and a width each smaller than or equal to 400 μm. The target roughness is represented by a maximum peak height after Gaussian filtering of smaller than 20 nm, and the target roughness is represented by an arithmetic mean height after Gaussian filtering of smaller than 0.7 nm. The support layer substrate can achieve better bonding results and improve a bonding efficiency. The obtained composite substrate has higher bonding strength and a high production yield, thereby ensuring quality of the electronic device and reducing production costs.

### CROSS-REFERENCE TO RELATED APPLICATION

This application claims priority to Chinese Patent Application No. 202311754631.8, filed on Dec. 20, 2023, which is herein incorporated by reference in its entirety.

### TECHNICAL FIELD

The disclosure relates to the field of electronic device processing and manufacturing technologies, and more particularly to a support layer substrate, a composite substrate, and an electronic device.

### BACKGROUND

In recent years, in accordance with a high performance of mobile phones, higher performance requirements have been put forward for the elastic wave device. One of the high performance requirements is to improve temperature stability of an elastic wave filter chip. Lithium tantalate (LiTaO₃) and lithium niobate (LiNbOₓ) are piezoelectric materials with a large electromechanical coupling coefficient, which are suitable for achieving wide-band filtering characteristics. Therefore, LiTaO₃ and LiNbOₓ are widely used in the piezoelectric materials of the elastic wave device. However, LiTaO₃ and LiNbOₓ have poor temperature stability. The elastic wave filter manufactured by using the aforementioned piezoelectric materials has a problem that passband depends on temperature.

Some technologies have been proposed to obtain piezoelectric materials with large electromechanical coupling coefficients and good temperature stability. For example, a thin piezoelectric layer is bonded to a support layer substrate with a low thermal expansion coefficient, which provides support and mechanical coupling. Therefore, the temperature stability can be improved by suppressing expansion and contraction caused by temperature changes. Specifically, a key technology for this kind of elastic wave device involves bonding the piezoelectric layer to the support layer substrate, and bonding quality between the piezoelectric layer and the support layer substrate will impact the performance and cost of the elastic wave device.

### SUMMARY

An objective of the disclosure is to provide a support layer substrate, a composite substrate and an electronic device, which can improve bonding area and bonding strength, so as to ensure quality of the electronic device, and reduce production costs.

An embodiment of the disclosure provides a support layer substrate having a main support surface. Each sampling area on the main support surface achieves a target roughness, and each sampling area is defined as an area with a length and a width each smaller than or equal to 400 microns (μm). The target roughness is represented by a maximum peak height after Gaussian filtering of smaller than 20 nanometers (nm), and the target roughness is represented by an arithmetic mean height after Gaussian filtering of smaller than 0.7 nm.

Embodiments of the disclosure further provide a composite substrate, including: the support layer substrate described in the aforementioned embodiment and a piezoelectric layer. The piezoelectric layer is bonded to the main support surface of the support layer substrate.

The embodiments of the disclosure further provide a preparation method of the composite substrate, including: a polishing process and a bonding process.

In the polishing process, a support layer material is polished to obtain a polished support layer material. A roughness of a polished surface of the polished support layer material is measured, and a support layer substrate is obtained until each sampling area on the polished surface achieves a target roughness. The polished surface is used as a main support surface of the support layer substrate. The sampling area is an area with a length smaller than or equal to 400 μm and a width smaller than or equal to 400 μm. The target roughness is represented by a maximum peak height after Gaussian filtering which is smaller than 20 nm.

In the bonding process, a piezoelectric layer is bonded to the main support surface of the support layer substrate by a direct pressing method.

The embodiments of the disclosure further provide an electronic device, including: the support layer substrate described in the aforementioned embodiment, the composite substrate described in the aforementioned embodiment, or the composite substrate prepared by the preparation method of the composite substrate described in the aforementioned embodiment.

The above embodiments of the disclosure have at least one of the following beneficial effects. Through setting that each sampling area on the main support surface of the support layer substrate provided by the embodiments of the disclosure achieves the target roughness, better bonding results can be achieved, and bonding efficiency can be improved. The obtained composite substrate has higher bonding strength and a high production yield, thereby ensuring the quality of the electronic device, and reducing the production costs.

### BRIEF DESCRIPTION OF DRAWINGS

In order to make the technical solutions described in embodiments of the present disclosure more clearly, the drawings used for description of some embodiments are described. Apparently, the drawings in the following description only illustrate some embodiments of the present disclosure. For those skilled in the art, other drawings may be acquired according to the drawings without any creative work.

FIG. 1 illustrates a schematic structural diagram from a top-down perspective of a support layer substrate according to an embodiment of the disclosure.

FIG. 2 illustrates a schematic structural diagram of a composite substrate according to an embodiment of the disclosure.

FIG. 3 illustrates a schematic structural diagram of an electronic device according to an embodiment of the disclosure.

FIG. 4 illustrates a schematic diagram of a blade test method illustrated by using a side perspective of the composite substrate according to an embodiment of the disclosure.

FIG. 5 illustrates a schematic diagram of the blade test method illustrated by using a top-down perspective of the composite substrate according to an embodiment of the disclosure.

FIG. 6 illustrates a schematic diagram of a peel distance of the composite substrate under the blade test method according to an embodiment of the disclosure.

FIG. 7 illustrates a surface detection diagram of a sample 1 obtained in an experiment 1 according to an embodiment of the disclosure.

FIG. 8 illustrates a surface detection diagram of the sample 1 obtained in the experiment 1 after thinning a lithium tantalate substrate according to an embodiment of the disclosure.

FIG. 9 illustrates a surface detection diagram of a sample 2 obtained in an experiment 2 according to an embodiment of the disclosure.

FIG. 10 illustrates a surface detection diagram of the sample 2 obtained in the experiment 2 after thinning a lithium tantalate substrate according to an embodiment of the disclosure.

FIG. 11 illustrates a surface detection diagram of a sample 3 obtained in an experiment 3 according to an embodiment of the disclosure.

FIG. 12 illustrates a surface detection diagram of the sample 3 obtained in the experiment 3 after thinning a lithium tantalate substrate according to an embodiment of the disclosure.

FIG. 13 illustrates a surface detection diagram of a sample 4 obtained in an experiment 4 according to an embodiment of the disclosure.

FIG. 14 illustrates a surface detection diagram of a sample 5 obtained in an experiment 5 according to an embodiment of the disclosure.

### DETAILED DESCRIPTION OF EMBODIMENTS

The technical solutions in embodiments of the present disclosure are clearly and completely described in conjunction with the drawings in the embodiments of the present disclosure. It may be understood that the embodiments are only used to explain but not used to limit the present disclosure. In addition, it should be noted that for ease of description, only some, but not all, of structures relevant to the present disclosure are shown in the drawings. All other embodiments acquired by those skilled in the art based on the embodiments in the present disclosure without the creative work are all within the scope of the present disclosure.

“Embodiment” mentioned in the present disclosure means that specific features, structures, or characteristics described in conjunction with embodiments may be included in at least one embodiment of the present disclosure. Some embodiments including the phrase appearing in various positions in the specification does not necessarily refer to the same embodiment, and does not independents or alternative embodiment that are mutually exclusive with other embodiments. Those skilled in the art explicitly and implicitly understand that the embodiments described in the present disclosure can be combined with other embodiments.

The terms “first”, “second”, and the like used in the present disclosure are used to distinguish different objects, and are not intended to describe a specific order. Furthermore, the terms “include” and “have”, and any modification thereof are intended to cover un-exclusive inclusion. For example, a process, method, system, product, or device that includes a series of operations or units is not limited to the listed operations or units, but optionally also includes operations or units not listed, or optionally includes other operations or units inherent to the process, method, product, or device.

Furthermore, although the terms “first”, “second”, and the like are used several times in the present disclosure to describe various data (various components, various applications, various instructions, or various operations) and the like, the various data (various components, various applications, various instructions, or various operations) should not be limited by the terms. The terms are only used to distinguish one data (component, application, instruction, or operation) from another data (component, application, instruction, or operation). For example, first position information may be referred to as second position information, and the second position information may be referred to as the first position information, simply because the scopes included in both of them are different, without departing from the scope of the present disclosure. Both the first position information and the second position information are collections of various position and pose information, but both of them are not the same collections of position and pose information.

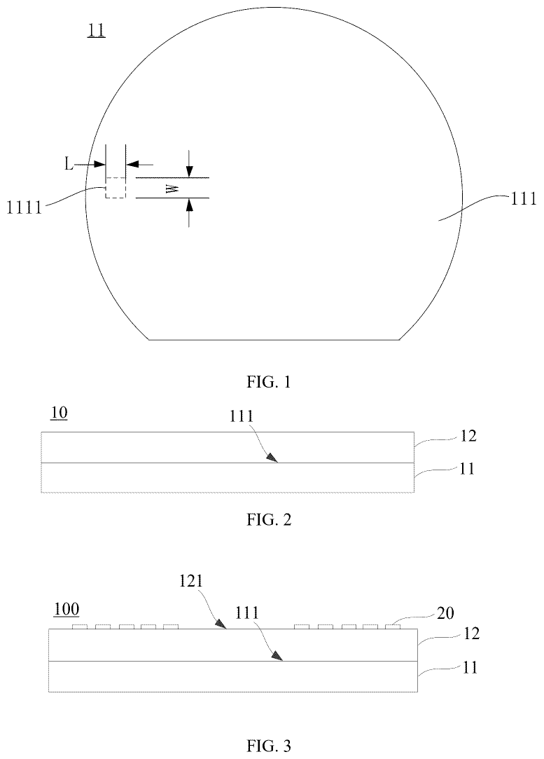

As shown in FIG. 1, an embodiment of the disclosure provides a support layer substrate 11. The support layer substrate 11 has a main support surface 111, and each sampling area 1111 on the main support surface 111 achieves a target roughness. The sampling area 1111 is defined as an area with a length L and a width W each smaller than or equal to 400 μm. The target roughness is represented by a maximum peak height after Gaussian filtering of smaller than 20 nm, and the target roughness is represented by an arithmetic mean height after Gaussian filtering of smaller than 0.7 nm.

Specifically, according to ISO 25178, the roughness can be represented by the arithmetic mean height Sa, a maximum height Sz, a root mean square height Sq, the maximum peak height Sp or other parameters. Among them, the maximum peak height Sp is a height of a maximum point in a definition area (i.e., the sampling area 1111 in the disclosure), and a specific meaning of the maximum peak height Sp can refer to instructions in ISO 25178. In the embodiment, the maximum peak height after Gaussian filtering is recorded as G−Sp. In simple terms, in the support layer substrate 11 provided by the embodiment, each sampling area 1111 on the main support surface 111 with L*W smaller than or equal to 400 μm*400 μm satisfies G−Sp≤20 nm.

In some embodiments, the length L of the sampling area 1111 is greater than or equal to 50 μm, and the width W of the sampling area 1111 is greater than or equal to 50 μm. That is, in the support layer substrate 11 provided by the embodiment, each sampling area 1111 on the main support surface 111 with L*W of 50 μm to 400 μm*50 μm to 400 μm satisfies G−Sp≤20 nm.

For example, in a 50 μm*50 μm area on the main support surface 111, G−Sp≤20 nm. In a 50 μm*100 μm area on the main support surface 111, G−Sp≤20 nm. In a 200 μm*50 μm area on the main support surface 111, G−Sp≤20 nm. In a 200 μm*250 μm area on the main support surface 111, G−Sp≤20 nm. In a 300 μm*400 μm area on the main support surface 111, G−Sp≤20 nm. In a 400 μm*400 μm area on the main support surface 111, G−Sp≤20 nm.

Specifically, G−Sp can be understood a new Sp value obtained by performing Gaussian regression filtering on a Sp value obtained from a roughness measurement device (e.g., a white light interferometer). Specifically, a processing function of the Gaussian regression filtering is

$$G ( x , y ) = \frac{1}{2 π {σ}^{2}} {e}^{- \frac{{x}^{2} + {y}^{2}}{2 {σ}^{2}}} ,$$

and its specific explanation can refer to a definition of a two-dimensional Gaussian function.

Since the roughness measurement is easy to be disturbed by vibration of a measuring stage, particles on a surface of a sample, a warpage of the sample itself and other factors, the roughness of the main support surface 111 of the support layer substrate 11 provided by the embodiment of the disclosure is represented by the roughness after Gaussian filtering. In actual measurement, the Gaussian filtering has little or no influence on the measurement result of Sp value. Therefore, in the embodiment, the target roughness can be represented by a maximum peak height which is smaller than 20 nm, and is represented by an arithmetic mean height after Gaussian filtering which is smaller than 0.7 nm.

Specifically, the arithmetic mean height after Gaussian filtering is recorded as G−Sa, and G−Sa can be understood a new Sa value obtained by performing Gaussian regression filtering on a Sa value obtained from the roughness measurement device (e.g., the white light interferometer). Each sampling area 1111 on the main support surface 111 satisfies G−Sa≤0.7 nm. In simple terms, in the support layer substrate 11 provided by the embodiment, each sampling area 1111 on the main support surface 111 with L*W smaller than or equal to 400 μm*400 μm satisfies G−Sa≤0.7 nm.

In some embodiments, the length L of the sampling area 1111 is greater than or equal to 50 μm, and the width W of the sampling area 1111 is greater than or equal to 50 μm. That is, in the support layer substrate 11 provided by the embodiment, each sampling area 1111 on the main support surface 111 with L*W of 50 μm to 400 μm*50 μm to 400 μm satisfies G−Sa≤0.7 nm.

For example, in a 50 μm*50 μm area on the main support surface 111, G−Sa≤0.7 nm. In a 50 μm*150 μm area on the main support surface 111, G−Sa≤0.7 nm. In a 100 μm*100 μm area on the main support surface 111, G−Sa≤0.7 nm. In a 250 μm*50 μm area on the main support surface 111, G−Sa≤0.7 nm. In a 250 μm*350 μm area on the main support surface 111, G−Sa≤0.7 nm. In a 300 μm*400 μm area on the main support surface 111, G−Sa≤0.7 nm. In a 400 μm*400 μm area on the main support surface 111, G−Sa≤0.7 nm.

In the support layer substrate 11 provided by some embodiments of the disclosure, each sampling area 1111 on the main support surface 111 satisfies the roughness of G−Sp≤20 nm and G−Sa≤0.7 nm. Alternatively, in the support layer substrate 11 provided by some embodiments of the disclosure, each sampling area 1111 on the main support surface 111 satisfies the roughness of Sp≤20 nm and G−Sa≤0.7 nm.

In some embodiments, the target roughness can be represented by a maximum peak height after Gaussian filtering of smaller than 15 nm, that is, G−Sp≤15 nm. That is, in the support layer substrate 11 provided by some embodiments of the disclosure, each sampling area 1111 on the main support surface 111 satisfies the roughness of G−Sp≤15 nm and G−Sa≤0.7 nm. Alternatively, in the support layer substrate 11 provided by some embodiments of the disclosure, each sampling area 1111 on the main support surface 111 satisfies the roughness of Sp≤15 nm and G−Sa≤0.7 nm.

The target roughness is determined by measuring the sampling area 1111 based on a shortwave filter. G−Sp is a Sp value of the sampling area 1111 processed by the shortwave filter. G−Sa is a Sa value of the sampling area 1111 processed by the shortwave filter. Specifically, Gaussian filters are divided into the following four types. (1) A long wavelength pass filter or a low frequency pass (waviness) filter is used to remove values below a cut-off wavelength of the long wavelength pass filter from data (i.e., which can achieve long wavelength filtering), or used to remove frequency components higher than those input at spatial frequency. The long wavelength pass filter or the low frequency pass filter is used to remove small-scale roughness components, so that a large-scale waviness surface structure is easier to be identified and measured. (2) A short wavelength pass filter or a high frequency pass (roughness) filter is used to remove values above a cut-off wavelength of the short wavelength pass filter from data (i.e., which can achieve short wavelength filtering), or used to remove frequency components lower than those input at spatial frequency. The short wavelength pass filter or the high frequency pass filter is used to remove large-scale waviness components, so that the small-scale roughness is easier to be identified and measured. (3) A band pass filter is used to shielding data that fails below a cut-off value of lower spatial frequency or shorter length, and above a cut-off value of higher spatial frequency or longer length. (4) A band-stop filter (i.e., a notch filter) is opposite to the band pass filter, and is used to block data with spatial frequencies between input frequency ranges or wavelengths between input wavelength ranges. In the embodiment, since an expected roughness Sa of the main support surface 111 is in a range of 0 nm to 2 nm, the roughness processed by the shortwave filter is selected to represent the target roughness.

In some embodiments, a cut-off wavelength of the shortwave filter is smaller than 50 μm, that is, the target roughness in the embodiment is obtained based on ISO 25178 under a measurement condition that with the cut-off wavelength based on the shortwave filter is smaller than 50 μm. The aforementioned G−Sp is a Sp value measured for the sampling area 1111 under the measurement condition that with the cut-off wavelength of the shortwave filter is smaller than 50 μm, and the aforementioned G−Sa is a Sa value measured for the sampling area 1111 under the measurement condition that with the cut-off wavelength of the shortwave filter is smaller than 50 μm.

In a specific embodiment of the disclosure, the aforementioned G−Sp and G−Sa are roughnesses measured by using a 3D optical contour measuring instrument (e.g., a ContourX-200 device) as a measurement tool and an operating software Vision 64 (which provides a Gaussian regression filter analysis function) of Bruker® company. That is, for the support layer substrate 11 provided in the embodiment, under measurement conditions of the ContourX-200 device as the measuring tool and the operating software Vision64 of Bruker® company, the Sp value measured at each sampling area 1111 on the main support surface 111 is smaller than or equal to 20 nm, and the Sa value is smaller than or equal to 0.7 nm.

In the specific embodiment of the disclosure, the support layer substrate 11 is formed by processing one of the support layer materials. The support layer materials include polycrystalline magnesium aluminum spinel, polycrystalline sapphire, and single crystal sapphire. Specifically, the support layer substrate 11 can be formed by processing one selected from the group consisting of the polycrystalline magnesium aluminum spinel, the polycrystalline sapphire, and the single crystal sapphire.

As shown in FIG. 2, the embodiments of the disclosure further provide a composite substrate 10, and the composite substrate 10 includes the support layer substrate 11 described in any one of the aforementioned embodiments, and a piezoelectric layer 12. The piezoelectric layer 12 is bonded to the main support surface 111 of the support layer substrate 11. The piezoelectric layer 12 can be a lithium tantalate substrate. Specifically, the piezoelectric layer 12 is bonded to the support layer substrate 11 via van der Waals force (also referred to as intermolecular force). A process for bonding the piezoelectric layer 12 to the support layer substrate 11 can be high temperature vacuum bonding or room temperature vacuum bonding. The high temperature vacuum bonding has a low requirement for the surface of the support layer substrate 11. However, due to the characteristic of high temperature, some materials are not suitable for the high temperature vacuum bonding. For example, a curie temperature of the lithium tantalate substrate is smaller than 650 Celsius degrees (° C.), thus the lithium tantalate substrate is not suitable for the high temperature vacuum bonding. The composite substrate 10 provided by the embodiment has a better bonding quality due to the use of the aforementioned support layer substrate 11. Therefore, using the room temperature vacuum bonding and using the van der Waals force for adhering can make the bonding area of the composite substrate 10 reach more than 95%, and make the bonding force reach a maximum level of the room temperature bonding.

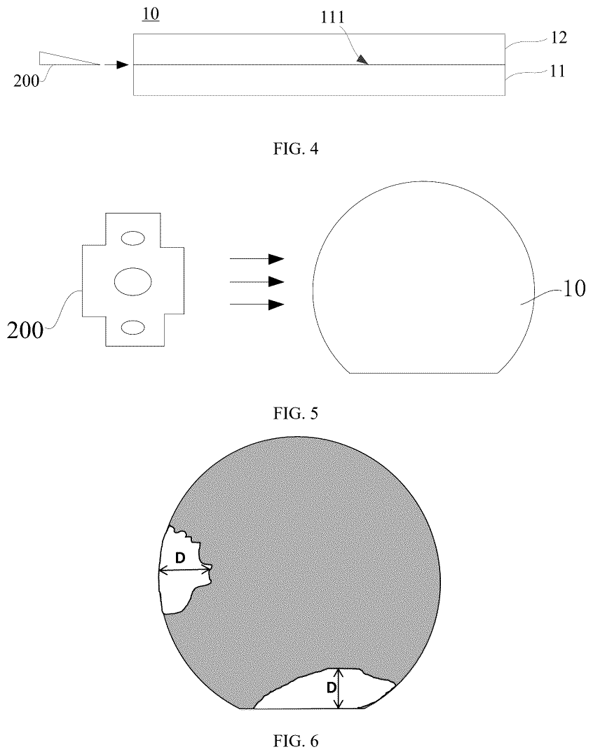

A peel distance of the piezoelectric layer 12 is smaller than or equal to 3 millimeters (mm) when the composite substrate 10 provided by the embodiment is tested by using a blade test method. Specifically, as shown in FIG. 4 and FIG. 5, a blade 200 is inserted between the piezoelectric layer 12 and the support layer substrate 11 provided by the embodiment of the disclosure, as shown in FIG. 6, a peel distance D of the piezoelectric layer 12 is smaller than or equal to 3 mm. In the blade test method, a thickness of the blade 200 is in a range of 100 μm to 200 μm, an insertion force is in a range of 1 newton (N) to 20 N, an insertion speed is in a range of 1 millimeter per second (mm/s) to 3 mm/s, an insertion angle needs to be as parallel as possible to the support layer substrate 11, and an angle between the blade 200 and the support layer substrate 11 is smaller than 5°. Other implementation methods or conditions of the blade test method can refer to a traditional blade test method, which will not be elaborated here.

In some embodiments, a thickness of the piezoelectric layer 12 is smaller than 10 μm. In the embodiment, the piezoelectric layer 12 is bonded to the support layer substrate 11 via the van der Waals force, so that the peel distance can still be guaranteed to be smaller than or equal to 3 mm when the thickness of the piezoelectric layer 12 is processed to smaller than 10 μm, and the bonding effect is good.

The embodiments of the disclosure further provide a preparation method of the composite substrate 10, and the preparation method includes a polishing process S1 and a bonding process S2.

In the polishing process S1, a support layer material is polished to obtain the polished support layer material, and a roughness of a polished surface of the polished support layer material is measured, and a support layer substrate 11 is obtained until any sampling area on the polished surface achieves a target roughness. The polished surface is used as a main support surface 111 of the support layer substrate 11. The sampling area 1111 is an area with a length smaller than or equal to 400 μm. The target roughness is represented by a maximum peak height after Gaussian filtering of smaller than 20 nm, and the target roughness is represented by an arithmetic mean height after Gaussian filtering of smaller than 0.7 nm.

In the bonding process S2, the piezoelectric layer 12 is bonded to the main support surface 111 of the support layer substrate 11 by a direct pressing method.

In the preparation method of the composite substrate 10 provided by the embodiments of the disclosure, a surface of the support layer material is polished to the target roughness (i.e., G−Sp≤20 nm, and G−Sa≤0.7 nm) to obtain the support layer substrate 11 firstly, then the piezoelectric layer 12 is bonded to the support layer substrate 11 to obtain the composite substrate 10, and the obtained composite substrate 10 has a higher bonding area and higher bonding quality. That is, in the step S1, the support layer material is polished to obtain the support layer substrate 11 with G−Sp≤20 nm and G−Sa≤0.7 nm for each sampling area 1111. In some embodiments, in the step S2, the room temperature bonding technology can be used. Through making the support layer substrate 11 satisfy the aforementioned specific roughness conditions, good bonding strength and a large bonding area can be obtained even if the room temperature bonding technology is used. Therefore, the support layer substrate 11 can be applied for bonding to the piezoelectric layer 12 of different materials, so that the material restrictions of the piezoelectric layer 12 are smaller.

For example, the preparation method of the composite substrate 10 provided by some embodiments of the disclosure includes the following specific steps.

In step X11, a material such as the polycrystalline magnesium aluminum spinel, the polycrystalline sapphire or the single crystal sapphire required for the support layer substrate 11 is determined. A thickness of the crystal (i.e., the support layer material) is processed into a thickness range required for the support layer substrate 11 by multi-line cutting. At this time, the support layer material is in a line cutting state with many parallel line cutting marks on the surface, which needs to be roughly ground.

In step X12, a diamond grinding liquid containing agglomerated diamond particles is used for roughly grinding, a particle size of each diamond particle is in a range of 0.5 μm to 2.5 μm. After the diamond particles agglomerate into a spherical shape, a particle size of the spherical diamond particle is in a range of 25 μm to 40 μm. The spherical diamond particles can reduce roughness and scratch depth of a grinding surface of the support layer material while ensuring rapid removal. After completing the step X12, a Sa of the roughly ground surface of the support layer material is in a range of 5 nm to 15 nm.

In step X13, the roughly ground support layer material is finely ground. A polycrystalline diamond grinding fluid with a particle size in a range of 50 nm to 100 nm is combined with a tin disc to finely grind the roughly ground support layer material. After finely grinding, Sa of the finely ground surface of the support layer material is smaller than 2 nm.

In step X14, chemical mechanical polishing (CMP) is performed on the finely ground support layer material. A silica sol polishing liquid with a particle size in a range of 30 nm to 80 nm is used for CMP, a polishing pressure is in a range of 0.05 kilograms per square centimeter (kg/cm²) to 0.3 kg/cm², and a polishing speed is in a range of 15 revolutions per minute (rpm) to 35 rpm. During CMP, it is sufficient to remove the scratches on a processing surface of the tin disc. After CMP, a finished support layer substrate 11 with the sampling area 1111 of the main support surface 111 reaching the target roughness (for example, G−Sp≤20 nm, G−Sa≤0.7 nm) can be obtained.

In step X21, surface ion activation is performed on a finished piezoelectric layer 12 and the main support surface 111 of the finished support layer substrate 11. Ion beam power is in a range of 5 electron volts (eV) to 15 eV, and a bonding pressure is in a range of 10000 N to 50000 N. After bonding for 1 minute (min) to 2 min, a successfully bonded composite substrate 10 is obtained.

Specifically, the steps X11-X14 are an example for specific implementation steps of the step S1, and the step X21 is an example for specific implementation steps of the step S2. Specific process conditions of the aforementioned roughly grinding, finely grinding, polishing and bonding steps can be adjusted according to actual needs.

As shown in FIG. 3, the embodiments of the disclosure further provides an electronic device 100, and the electronic device 100 includes the support layer substrate 1 described in any of the aforementioned embodiments, the composite substrate 10 described in any of the aforementioned embodiments, or the composite substrate 10 prepared by the aforementioned preparation method of the composite substrate 10. As shown in FIG. 3, the electronic device 100 can be an elastic wave device, such as a surface acoustic wave (SAW) device, more specifically a temperature compensated surface acoustic wave (Tc-SAW) device. The electronic device 100 includes the composite substrate 10 formed by bonding the support layer substrate 11 to the piezoelectric layer 12, and electrodes 20 (which can refer to electrodes of a traditional SAW device) disposed on a main surface 121 (i.e., a surface of the piezoelectric layer 12 facing away from the support layer substrate 11) of the piezoelectric layer 12. Alternatively, the electronic device 100 can further be another device such as a light-emitting diode (LED) device, which can combine the support layer substrate 11 with another functional substrate.

Beneficial effects of the support layer substrate 11, the composite substrate 10 and the preparation method thereof, and the electronic device 100 provided by the embodiments of the disclosure are described below by experiment 1 to experiment 7.

### Experiment 1

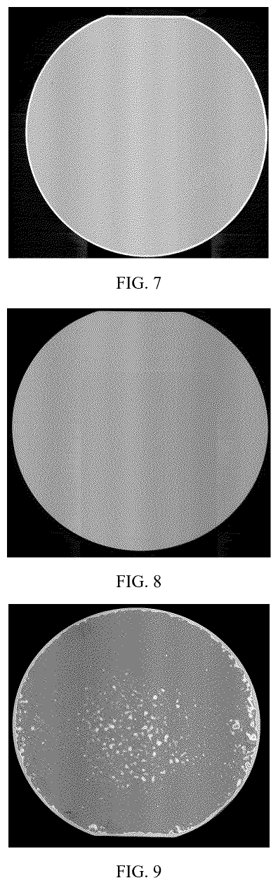

The magnesium aluminum spinel is used as a support layer material. After an ingot of the magnesium aluminum spinel is sliced by multi-line cutting, agglomerated spherical diamond particles with a particle size of 30 μm are selected to grind the sliced magnesium aluminum spinel, and then a single crystal diamond liquid with a particle size of 100 nm is combined with the tin plate to roughly polish the ground magnesium aluminum spinel. Finally, a silica sol polishing liquid with a particle size of 80 nm is used to finely polish the roughly polished magnesium aluminum spinel, to thereby obtain a finished spinel substrate. A thickness of the finished spinel substrate is 250 μm, and a roughness of a main support surface (i.e., the polished surface) of the finished spinel substrate satisfies G−Sp≤20 nm and G−Sa≤0.7 nm. The room temperature vacuum bonding is performed on the finished spinel substrate and a lithium tantalate substrate with a thickness of 200 μm to obtain a sample 1. The bonding ion beam power is 15 eV, the bonding pressure is 15000 N, and the bonding period is 1 min. The obtained sample 1 is shown in FIG. 7, it can be seen that the bonding area of the sample 1 basically achieves 100%. After the thickness of the lithium tantalate substrate is processed from 200 μm to 5 μm, the bonding area of the sample 1 is still close to 100%, and there is no piezoelectric layer peeling at the edge (as shown in FIG. 8).

### Experiment 2

The magnesium aluminum spinel is used as a support layer material. After the ingot of the magnesium aluminum spinel is sliced by multi-line cutting, the agglomerated spherical diamond particles with the particle size of 30 μm are selected to grind the sliced magnesium aluminum spinel, and then the single crystal diamond liquid with the particle size of 100 nm is combined with the tin plate to roughly polish the ground magnesium aluminum spinel. Finally, a silica sol polishing liquid with a particle size of 85 nm is used to finely polish the roughly polished magnesium aluminum spinel, to thereby obtain a finished spinel substrate. A thickness of the finished spinel substrate is 250 μm, and a roughness of a polished surface (i.e., the main support surface) of the finished spinel substrate satisfies G−Sp>20 nm and G−Sa≤0.7 nm. The room temperature vacuum bonding is performed on the finished spinel substrate and the lithium tantalate substrate with the thickness of 200 μm to obtain a sample 2. The bonding ion beam power is 15 eV, the bonding pressure is 15000 N, and the bonding period is 1 min. The obtained sample 2 is shown in FIG. 9, it can be seen that the bonding area of the sample 2 is only about 75%. After the thickness of the lithium tantalate substrate is processed from 200 μm to 5 μm, as shown in FIG. 10, there is obvious piezoelectric layer peeling at the edge. Since G−Sp>20 nm, an interior of the sample 2 is filled with densely packed small areas of bonding failure, and a large amount of peeling occurred when the lithium tantalate substrate is thinned to 5 μm.

### Experiment 3

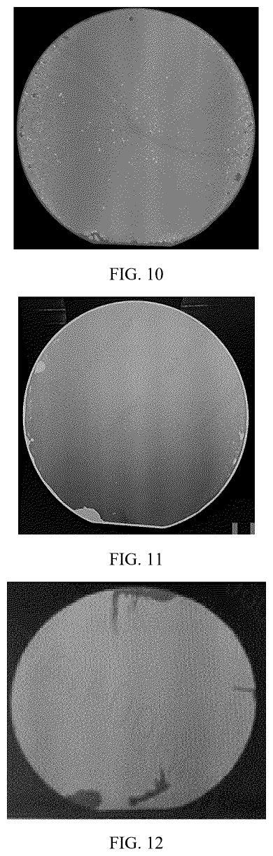

The magnesium aluminum spinel is used as a support layer material. After the ingot of the magnesium aluminum spinel is sliced by multi-line cutting, the agglomerated spherical diamond particles with the particle size of 30 μm are selected to grind the sliced magnesium aluminum spinel, and then the single crystal diamond liquid with the particle size of 100 nm is combined with the tin plate to roughly polish the ground magnesium aluminum spinel. Finally, the silica sol polishing liquid with the particle size of 85 nm is used to finely polish the roughly polished magnesium aluminum spinel, to thereby obtain a finished spinel substrate. A thickness of the finished spinel substrate is 250 μm, and a roughness of a polished surface (i.e., the main support surface) of the finished spinel substrate satisfies G−Sp≤20 nm and G−Sa>0.7 nm. The room temperature vacuum bonding is performed on the finished spinel substrate and the lithium tantalate substrate with the thickness of 200 μm to obtain a sample 3. The bonding ion beam power is 15 eV, the bonding pressure is 15000 N, and the bonding period is 1 min. The obtained sample 3 is shown in FIG. 11, it can be seen that the bonding area of the sample 3 is only about 75%. After the thickness of the lithium tantalate substrate is processed from 200 μm to 5 μm, as shown in FIG. 12, there is obvious piezoelectric layer peeling at the edge.

### Experiment 4

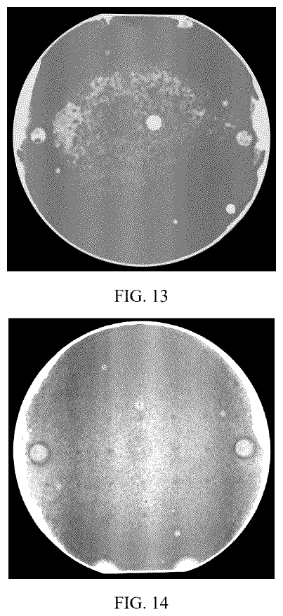

The magnesium aluminum spinel is used as a support layer material. After the ingot of the magnesium aluminum spinel is sliced by multi-line cutting, the agglomerated spherical diamond particles with the particle size of 30 μm are selected to grind the sliced magnesium aluminum spinel, and then the single crystal diamond liquid with the particle size of 100 nm is combined with the tin plate to roughly polish the ground magnesium aluminum spinel. Finally, a silica sol polishing liquid with a particle size of 90 nm is used to finely polish the roughly polished magnesium aluminum spinel, to thereby obtain a finished spinel substrate. A thickness of the finished spinel substrate is 250 μm, and a roughness of a polished surface (i.e., the main support surface) of the finished spinel substrate satisfies G−Sp>20 nm and G−Sa>0.7 nm. The room temperature vacuum bonding is performed on the finished spinel substrate and the lithium tantalate substrate with the thickness of 200 μm to obtain a sample 4. The bonding ion beam power is 15 eV, the bonding pressure is 15000 N, and the bonding period is 1 min. The obtained sample 4 is shown in FIG. 13, it can be seen that the bonding area of the sample 4 is only about 40%. After the thickness of the lithium tantalate substrate is processed from 200 μm to 5 μm, there is obvious piezoelectric layer peeling at the edge.

### Experiment 5

The magnesium aluminum spinel is used as a support layer material. After the ingot of the magnesium aluminum spinel is sliced by multi-line cutting, the agglomerated spherical diamond particles with the particle size of 30 μm are selected to grind the sliced magnesium aluminum spinel, and then the single crystal diamond liquid with the particle size of 100 nm is combined with the tin plate to roughly polish the ground magnesium aluminum spinel. Finally, a silica sol polishing liquid with a particle size of 100 nm is used to finely polish the roughly polished magnesium aluminum spinel, to thereby obtain a finished spinel substrate. A thickness of the finished spinel substrate is 250 μm, and a roughness of a polished surface (i.e., the main support surface) of the finished spinel substrate satisfies that G−Sp is much greater than 20 nm and G−Sa is much greater than 0.7 nm. The room temperature vacuum bonding is performed on the finished spinel substrate and the lithium tantalate substrate with the thickness of 200 μm to obtain a sample 5. The bonding ion beam power is 15 eV, the bonding pressure is 15000 N, and the bonding period is 1 min. The obtained sample 5 is shown in FIG. 14, it can be seen that there is basically no successful bonding on the entire surface of the substrate. The result of the bonding strength tested by the blade test method is not good (NG), and the lithium tantalate substrate of the sample 5 cannot be thinned.

### Experiment 6

The single crystal sapphire is used as a support layer material. After an ingot of the single crystal sapphire is sliced by multi-line cutting, the agglomerated spherical diamond particles with the particle size of 30 μm are selected to grind the single crystal sapphire, and then the silica sol polishing liquid with the particle size of 80 nm is used to finely polish the ground single crystal sapphire, to thereby obtain a finished sapphire substrate. A thickness of the finished sapphire substrate is 250 μm, and a roughness of a polished surface of the finished sapphire substrate satisfies G−Sp≤20 nm and G−Sa≤0.7 nm. The room temperature vacuum bonding is performed on the finished sapphire substrate and the lithium tantalate substrate with the thickness of 200 μm to obtain a sample 6. The bonding ion beam power is 15 eV, the bonding pressure is 15000 N, and the bonding period is 1 min. The bonding area of the sample 6 basically achieves 100%. After the thickness of the lithium tantalate substrate is processed from 200 μm to 5 μm, the bonding area of the sample 6 is still close to 100%, and there is no piezoelectric layer peeling at the edge.

### Experiment 7

The polycrystalline sapphire is used as a support layer material. After the polycrystalline sapphire is ground, the agglomerated spherical diamond particles with the particle size of 30 μm are selected to ground the first ground polycrystalline sapphire, and then a silica sol polishing liquid with a particle size of 60 nm is used to finely polish the second ground polycrystalline sapphire, to thereby obtain a finished polycrystalline sapphire substrate. A thickness of the finished polycrystalline sapphire substrate is 250 μm, and a roughness of a polished surface of the finished polycrystalline sapphire substrate satisfies G−Sp≤20 nm and G−Sa≤0.7 nm. The room temperature vacuum bonding is performed on the finished polycrystalline sapphire substrate and the lithium tantalate substrate with the thickness of 200 μm to obtain a sample 7. The bonding ion beam power is 15 eV, the bonding pressure is 15000 N, and the bonding period is 1 min. The bonding area of the sample 7 basically achieves 100%. After the thickness of the lithium tantalate substrate is processed from 200 μm to 5 μm, the bonding area of the sample 7 is still close to 100%, and there is no piezoelectric layer peeling at the edge.

A data table of experimental results from the experiment 1 to the experiment 7 is shown in Table 1. The bonding result Pass means successful bonding, and the bonding result NG means unsuccessful bonding. When the peel distance is smaller than or equal to 3 mm, the bonding result is Pass.

TABLE 1

| | | | | Bonding | Peel | Bonding |
|---|---|---|---|---|---|---|
| | Support layer material | G-Sa/nm | G-Sp/nm | area/% | distance/mm | result |
| Experiment 1 | Magnesium aluminum | 0.47 | 10.1 | 100 | 0.8 | Pass |
| | spinel | | | | | |
| Experiment 2 | Magnesium aluminum | 0.42 | 23.4 | 80 | 3.5 | NG |
| | spinel | | | | | |
| Experiment 3 | Magnesium aluminum | 0.78 | 11.4 | 90 | 5.8 | NG |
| | spinel | | | | | |
| Experiment 4 | Magnesium aluminum | 0.81 | 25.8 | 70 | 10.5 | NG |
| | spinel | | | | | |
| Experiment 5 | Magnesium aluminum | 1.23 | 35.7 | 0 | >50 | NG |
| | spinel | | | | | |
| Experiment 6 | Single crystal sapphire | 0.17 | 5.6 | 100 | 0.5 | Pass |
| Experiment 7 | Polycrystalline sapphire | 0.45 | 14.5 | 100 | 0.9 | Pass |

According to the above results from the experiment 1 to the experiment 7, when the roughness of the main support surface 111 of the support layer substrate 11 satisfies G−Sp within 20 nm, the support layer substrate 11 can be used to obtain a higher bonding area between the support layer substrate 11 and the piezoelectric layer 12, and the bonding effect is good. When the roughness of the main support surface 111 of the support layer substrate 11 satisfies G−Sp within 20 nm and G−Sa within 0.7 nm, a higher bonding area between the support layer substrate 11 and the piezoelectric layer 12 can be obtained, and the support layer substrate 11 and the piezoelectric layer 12 have high bonding strength, which is not easy to peel off. Therefore, the support layer substrate 11 provided by the embodiments can achieve a better bonding effect, and improve the bonding efficiency. The obtained composite substrate 10 has higher bonding strength and a high production yield, thereby ensuring the quality of the electronic device 100 and reducing the production cost.

The above are only some embodiments of the present disclosure, but are not to limit the scope of the present disclosure. The equivalent structures or equivalent process transformations made by using the description and the drawings of the present disclosure, or directly or indirectly applying the description and the drawings of the present disclosure to other relevant technical fields, are included in the scope of the present disclosure.

What is claimed is:

1. A support layer substrate having a main support surface, wherein each sampling area on the main support surface achieves a target roughness, and each sampling area is defined as an area with a length and a width each smaller than or equal to 400 μm; and the target roughness is represented by a maximum peak height after Gaussian filtering of smaller than 20 nm, and the target roughness is also represented by an arithmetic mean height after Gaussian filtering of smaller than 0.7 nm.

2. The support layer substrate according to claim 1, wherein each sampling area is an area with a length greater than or equal to 50 μm and a width greater than or equal to 50 μm.

3. The support layer substrate according to claim 1, wherein the target roughness is represented by a maximum peak height after Gaussian filtering of smaller than 15 nm.

4. The support layer substrate according to claim 1, wherein the target roughness is determined by measuring the sampling area using a shortwave filter.

5. The support layer substrate according to claim 4, wherein a cut-off wavelength of the shortwave filter is smaller than 50 μm.

6. The support layer substrate according to claim 1, wherein the support layer substrate is formed by processing one of the following materials: polycrystalline magnesium aluminum spinel, polycrystalline sapphire, and single crystal sapphire.

7. A composite substrate, comprising:
a support layer substrate having a main support surface, wherein each sampling area on the main support surface achieves a target roughness, and each sampling area is defined as an area with a length and a width each smaller than or equal to 400 μm; and the target roughness is represented by a maximum peak height after Gaussian filtering of smaller than 20 nm, and the target roughness is represented by an arithmetic mean height after Gaussian filtering of smaller than 0.7 nm; and
a piezoelectric layer, bonded to the main support surface of the support layer substrate.

8. The composite substrate according to claim 7, wherein the piezoelectric layer is bonded to the support layer substrate via van der Waals force.

9. The composite substrate according to claim 8, wherein a peel distance of the piezoelectric layer is smaller than or equal to 3 mm when the composite substrate is tested by using a blade test method.

10. The composite substrate according to claim 8, wherein a thickness of the piezoelectric layer is smaller than 10 μm.

11. The composite substrate according to claim 8, wherein a bonding area of the composite substrate is more than 95%.

12. The composite substrate according to claim 7, wherein each sampling area is an area with a length greater than or equal to 50 μm and a width greater than or equal to 50 μm.

13. The composite substrate according to claim 7, wherein the target roughness is a roughness obtained by measuring the sampling area based on a shortwave filter, and a cut-off wavelength of the shortwave filter is smaller than 50 μm.

14. The composite substrate according to claim 7, wherein the target roughness is represented by a maximum peak height after Gaussian filtering of smaller than 15 nm.

15. The composite substrate according to claim 7, wherein the support layer substrate is formed by processing one selected from the group consisting of polycrystalline magnesium aluminum spinel, polycrystalline sapphire, and single crystal sapphire, and the piezoelectric layer is a lithium tantalate substrate.

16. An electronic device, comprising:
a support layer substrate, comprising: a main support surface; wherein each sampling area on the main support surface achieves a target roughness, and each sampling area is defined as an area with a length and a width each greater than or equal to 50 μm and smaller than or equal to 400 μm;
and the target roughness is represented by a maximum peak height after Gaussian filtering of smaller than 20 nm, and the target roughness is represented by an arithmetic mean height after Gaussian filtering of smaller than 0.7 nm;
a piezoelectric layer, bonded to the support layer substrate to form a composite substrate; and
electrodes, disposed on a side of the piezoelectric layer facing away from the support layer substrate.

17. The electronic device according to claim 16, wherein the target roughness is represented by a maximum peak height after Gaussian filtering of smaller than 15 nm.

18. The electronic device according to claim 16, wherein a thickness of the piezoelectric layer is smaller than 10 μm.

19. The electronic device according to claim 16, wherein the electronic device is an elastic wave device.

20. The electronic device according to claim 16, wherein a bonding area of the composite substrate is more than 95%.
